(19) United States
(12) Patent Application Publication
(10) Pub. No.: US 2026/0147205 A1
(43) Pub. Date: May 28, 2026

(54) PANE, DEVICE, AND METHOD FOR THE THERMAL STABILIZATION OF A HOLOGRAM ELEMENT

(71) Applicant: SAINT-GOBAIN SEKURIT FRANCE, THOUROTTE (FR)

(72) Inventors: Marcel KLEIN, HERZOGENRATH (DE); Florian MANZ, HERZOGENRATH (DE); Nikolai BORCHMANN, HERZOGENRATH (DE); Semjon MOORAJ, HERZOGENRATH (DE); Robert BESLER, HERZOGENRATH (DE)

(21) Appl. No.: 19/483,706

(22) PCT Filed: Apr. 30, 2024
(86) PCT No.: PCT/EP2024/061889

§ 371 Date: Nov. 12, 2025

(30) Foreign Application Priority Data
May 30, 2023 (EP) 23175970.5

(51) Int. Cl. G02B 27/01; H05B 1/02; H05B 3/03; H05B 3/86; H05K 7/20

(52) U.S. Cl. CPC G02B 27/0101; H05B 1/0236; H05B 3/03; H05B 3/86; H05K 7/20145; H05K 7/20209; G02B 2027/0105; G02B 2027/0196; H05B 2203/013; H05B 2213/07

(57) ABSTRACT

A pane with thermal stabilization of at least one hologram element, includes at least one glass pane with an outer surface and an interior-side surface, at least one hologram element arranged on the outer surface or the interior-side surface of the at least one glass pane, wherein the at least one hologram element includes a photopolymer, and at least two temperature stabilization elements, wherein the at least two temperature stabilization elements are configured to stabilize the temperature of the at least one hologram element to a target temperature.

The invention relates to a pane with thermal stabilization of at least one hologram element, a device comprising the pane, a method for thermally stabilizing at least one hologram element, and the use of the pane.

It is common knowledge in the automotive sector and in architecture to incorporate additional features into glazing products to improve the properties of the product. A relevant example is the use of hologram elements attached to a pane and/or embedded in a laminated pane in order to provide visual information to the viewer in a pleasant manner.

Holograms can be used, for example, for head-up displays, wherein hologram elements are laminated between the panes of a laminated pane. The hologram may contain information recorded within it. The hologram can be activated by light emitted by a projector, and the information recorded in the hologram can thus be displayed to the viewer. Head-up displays based on the principle of holography are disclosed, for example, in publications WO 2012/156124A1, US 2019/0056596A1, U.S. Pat. No. 10,394,032B2, U.S. Pat. No. 10,061,069 B2, US 2015/205138A1, and WO 2022/101194A1 .

There are different types of holograms. They include, for example, reflection holograms or holograms based on the principle of guiding light waves in the hologram, so-called waveguides or waveguide holograms.

A photopolymer can be used as a holographic material of a hologram element, in which various optical functions can be implemented, e.g., wavelength-selective mirrors that become active for defined viewing angles.

The use of a photopolymer-containing hologram element for a head-up display is known, for example, from WO 2021/180471 A1.

WO2022/271905A1 discloses a windshield comprising a reflective layer, wherein the reflective layer may comprise a holographic optical element.

However, one of the challenges in implementing such photopolymer-containing hologram elements in glazing products is that the photopolymer is very sensitive to temperature changes. As soon as the temperature of the photopolymer deviates significantly from a predefined target temperature in which it is to be used, thermally induced physical dimensional changes cause a shift in the wavelength of the maximum reflected intensity. As a result, the optical function of the hologram element deteriorates or is even lost completely depending on the temperature change. Good optical performance is only guaranteed within a range of +5° C. around the predefined target temperature for the photopolymers typically used at present. Even a naturally occurring temperature fluctuation, caused for example by a change in the environment, can therefore already be decisive for such a hologram element. This can make it difficult or impossible to use a photopolymer-containing hologram element in a glazing product exposed to environmental conditions.

DE112020006068T5 discloses a window pane system comprising a window pane to be mounted on a mobile body, a device arranged on the window pane and comprising an organic element made of an organic material, a temperature sensor designed to detect a glass temperature of the window pane, a temperature and humidity sensor designed to detect a temperature and a humidity in an interior of the mobile body, and a control unit comprising a circuit that determines, on the basis of the glass temperature detected by the temperature sensor and the temperature and the humidity detected in the interior by the temperature and humidity sensor, whether the glass temperature exceeds a dew point temperature, if it is determined that the glass temperature is lower than or equal to the dew point temperature, switches on an electric heating wire or an electric heating film, which is attached to the window pane, or a defroster; and, if the glass temperature detected by the temperature sensor exceeds a specified temperature, switches off the electric heating wire or the electric heating film or the defroster.

WO2022/214369A1 discloses a laminated pane, comprising at least: an outer pane, an inner pane, and a thermoplastic intermediate layer arranged between the outer pane and the inner pane, an electrically conductive coating, and a reflective layer suitable for reflecting light, wherein the reflective layer may be a holographic optical element.

The present invention is therefore based on the objective of providing a pane, a device, and a method, which make a particularly precise thermal stabilization of a photopolymer-containing hologram element possible.

The objective of the present invention is achieved according to the invention by a pane according to claim 1, a device according to claim 11, and a method according to claim 13. Preferred embodiments result from the dependent claims. The invention also relates to the use of the pane as a projection surface for a head-up display.

The invention relates to a pane with thermal stabilization of at least one hologram element, comprising at least one glass pane with an outer surface and an interior-side surface, at least one hologram element arranged on the outer surface or the interior-side surface of the at least one glass pane, wherein the at least one hologram element comprises a photopolymer, and at least two temperature stabilization elements, wherein the at least two temperature stabilization elements are configured to stabilize the temperature of the at least one hologram element to a target temperature.

The pane is provided to separate the interior from the external environment in a window opening. The pane according to the invention comprises at least one glass pane, at least one hologram element, and at least two temperature stabilization elements. The glass pane has two surfaces (main surfaces), namely an outer surface and an interior-side surface, and a peripheral edge surface between the two main surfaces. The term “outer surface” refers to the main surface that, in the installed position, faces the external environment. The term “interior-side surface” refers to the main surface that, in the installed position, faces the interior. The at least one hologram element is arranged on said outer surface or the interior-side surface of the glass pane. The at least one hologram element is preferably arranged on the interior-side surface of the glass pane since the at least one hologram element is thus particularly well protected against damage caused by mechanical and/or chemical influences from the environment.

In one embodiment of the invention, the pane is designed as a laminated pane, wherein one glass pane is connected to a further glass pane via a thermoplastic intermediate layer. Below, in the case of a laminated pane, the one glass pane that must at least be present in the pane according to the invention is referred to as “the glass pane,” while the glass pane that is additionally present in the laminated pane is called “further glass pane” or “other glass pane.” In particular, a laminated pane comprises an outer pane and an inner pane, which are connected to each other via the thermoplastic intermediate layer. For the purpose of the invention, the term “inner pane” refers to the glass pane of the laminated pane that faces the interior. The term “outer pane” refers to the glass pane facing the external environment. The glass pane may represent the inner pane or the outer pane of the laminated pane and the further glass pane may represent the other one. The at least one hologram element may be located on the outer surface or the interior-side surface of the glass pane that is used as an inner pane or as an outer pane. If the glass pane is used as the outer pane of the laminated pane, the at least one hologram element is preferably located on the interior-side surface of the glass pane since this protects the at least one hologram element from damage caused by mechanical and/or chemical influences from the environment. Insofar as the glass pane represents the inner pane of a laminated pane, the at least one hologram element on both the outer surface and the interior-side surface of the glass pane is protected from these influences from the environment. In one embodiment of the invention, the at least one hologram element is located on the outer surface of the glass pane that is used as the inner pane of the laminated pane, which makes particularly advantageous temperature stabilization and regulation possible by a temperature stabilization element located between the inner pane and the outer pane. According to a further embodiment, the at least one hologram element is arranged on the interior-side surface of the glass pane when the glass pane is used as the inner pane of the laminated pane, since this makes it particularly easy to achieve temperature stabilization and regulation by a temperature stabilization element arranged outside (externally of) the glass pane and oriented toward the at least one hologram element. Such laminated panes are preferably used in the automotive sector as so-called laminated safety glass (VSG). The vehicle pane may, for example, be a windshield, side pane, rear pane, or roof pane.

In an alternative embodiment of the invention, the pane according to the invention is a monolithic pane which is designed as a single glass pane. Apart from the glass pane with the at least one hologram element, there is no further glass pane. In the case of a single glass pane, the at least one hologram element is preferably arranged on the interior-side surface of the glass pane since the at least one hologram element is thus protected against damage caused by mechanical and/or chemical influences from the environment. The pane can be used in particular as a so-called single-pane safety glass (ESG), wherein the glass pane is thermally tempered. The monolithic vehicle pane may, for example, be a side pane, rear pane, or roof pane.

According to an advantageous embodiment, the glass pane contains or consists of flat glass, preferably soda lime glass, borosilicate glass or quartz glass. The glass may be made of clear glass or of tinted or colored glass. A clear glass is a glass pane that has an integrated light transmittance of at least 90% in accordance with ISO 9050. Tinted or colored glass panes have lower integrated light transmittance. The same explanations also apply to the further glass pane (i.e., the inner pane or outer pane) if the pane is a laminated pane. The thickness of the glass pane can be selected freely to meet the requirements of the application. The thickness of the glass pane or of the further glass pane is usually from 0.5 mm to 5 mm.

The thermoplastic intermediate layer is preferably formed from at least one thermoplastic film, preferably a PVB film, EVA film, or PU film. Typical thicknesses for such films are within the range of 0.2 mm to 2 mm, in particular of 0.3 mm to 1 mm.

For the purpose of the invention, a hologram is a reflection hologram or a waveguide hologram that is arranged within a hologram element. The hologram element refers to the holographic medium in which the hologram is contained. The hologram element comprises a photopolymer. A hologram can be recorded in this photopolymer by exposure to a suitable light source. In the finished pane, the material of the hologram element is no longer light-sensitive since the photopolymer is changed during the process to such an extent that no further recording of a hologram is possible. The term “hologram element” refers to both the unexposed hologram element made of light-sensitive material and to the final hologram element with a recorded hologram. According to the invention, the final hologram element comprises at least one hologram, but preferably multiple individual holograms.

According to the invention, the at least one hologram element comprises a photopolymer. According to one embodiment, the at least one hologram element comprises, in addition to the photopolymer, a cover layer and/or a substrate layer. Preferably, the photopolymer is arranged between the cover layer and the substrate layer.

The thickness of the at least one hologram element is preferably from 10 μm to 500 μm, particularly preferably from 10 μm to 100 μm.

The photopolymer is not particularly limited. The photopolymer preferably comprises crosslinked polyurethane (PU) or polyacrylate.

The substrate layer of the at least one hologram element may, for example, be formed from polyamide (PA) film, polycarbonate (PC) film, or cellulose triacetate (TAC) film. The layer thickness of the substrate layer is preferably from 35 μm to 60 μm.

The cover layer of the at least one hologram element may, for example, be formed from polyamide (PA) film, polycarbonate (PC) film, cellulose triacetate (TAC) film, polymethyl methacrylate (PMMA) film, or polyethylene terephthalate (PET) film. The layer thickness of the cover layer is preferably from 35 μm to 60 μm.

In one embodiment, the photopolymer is formed as a photopolymer layer. The layer thickness of the photopolymer or photopolymer layer is preferably from 8 μm to 18 μm.

The at least one hologram element may be fastened in or to the pane by means of commonly used fasteners. Preferably, the at least one hologram element is laminated between two polyvinyl butyral (PVB) films, two ethylene vinyl acetate (EVA) films, or two films made of thermoplastic polyurethane (TPU). Alternatively, the at least one hologram element may be fastened in or to the pane via an optically clear adhesive (OCA). Suitable optically clear adhesives are known to those skilled in the art. An easy connection of the at least one hologram element with other components of the pane can thus be achieved.

According to the invention, the pane is provided with thermal stabilization for the at least one hologram element. In particular, the thermal stabilization is realized by means of the at least two temperature stabilization elements, which are configured to stabilize the temperature of the at least one hologram element to a target temperature.

For the purpose of the invention, the “target temperature” is a predefined temperature at which the photopolymer of the at least one hologram element is to fulfill its function as a holographic material. The target temperature is not particularly limited. For example, a room temperature of 25° C. may be defined as the target temperature. Alternatively, the target temperature may also be a higher temperature. Preferably, the target temperature is less than 90° C. More preferably, the target temperature is in a range of 15° C. to 50° C. since this range is energetically advantageous.

According to the invention, “temperature stabilization” or “thermal stabilization” of the at least one hologram element means that the at least one hologram element is thermally stabilized by means of the temperature stabilization elements such that its temperature deviates as little as possible from the target temperature during its use to display the hologram. Preferably, the at least one hologram element is thermally stabilized such that its temperature is in a range of (target temperature −10° C.) to (target temperature +10° C.), more preferably of (target temperature −5° C.) to (target temperature +5° C.).

The at least two temperature stabilization elements according to the invention are not particularly limited as long as they are configured to stabilize the temperature of the at least one hologram element to the target temperature.

According to a preferred embodiment, the at least two temperature stabilization elements are independently selected from the group consisting of a heatable coating, a thermally insulating coating, and an (external) nozzle.

In one embodiment of the invention, at least one of the at least two temperature stabilization elements is a heatable coating. By means of the heatable coating, the at least one hologram element can be heated efficiently since a heatable coating itself can be heated quickly. According to one embodiment, the heatable coating comprises one or more, for example two, three, or four functional layers. According to a preferred embodiment, the functional layer comprises at least one metal, for example silver, gold, copper, nickel, and/or chromium, or a metal alloy. The functional layer particularly preferably comprises at least 90 wt. % of the metal, in particular at least 99.9 wt. % of the metal. The functional layer may consist of the metal or the metal alloy. The functional layer particularly preferably comprises silver or a silver-containing alloy. Such a functional layer has particularly advantageous heatability with simultaneously high transmittance within the visible spectral range. The thickness of a functional layer is preferably from 5 nm to 50 nm, particularly preferably from 8 nm to 25 nm. In this range for the thickness of the functional layer, advantageously high transmittance in the visible spectral range and particularly advantageous heatability are achieved.

Preferably, at least one dielectric layer is arranged in each case between two adjacent functional layers of the heatable coating. Preferably, a further dielectric layer is arranged below the first and/or above the last functional layer. A dielectric layer contains at least one individual layer made of a dielectric material, for example containing a nitride, such as silicon nitride, or an oxide, such as aluminum oxide. Dielectric layers can, however, also comprise multiple individual layers, e.g., individual layers of a dielectric material, smoothing layers, matching layers, blocker layers, and/or anti-reflective layers. The thickness of a dielectric layer is, for example, from 10 nm to 200 nm.

This layer structure is generally obtained by a sequence of deposition operations performed by a vacuum method, such as magnetic-field-assisted cathodic sputtering.

According to a further embodiment, the functional layer of the heatable coating comprises indium tin oxide (ITO), fluorine-doped tin oxide (SnO₂:F), or aluminum-doped zinc oxide (ZnO:Al). Such a functional layer preferably has a layer thickness of 8 nm to 25 nm, particularly preferably of 13 nm to 19 nm. This is particularly advantageous with regard to the transparency, color neutrality, and sheet resistance of the heatable coating.

In a preferred embodiment, the heatable coating is provided with busbars that are connected to the poles of a voltage source. Preferably, at least two external busbars provided for connection to a voltage source are connected to the heatable coating such that a current path for a heating current is formed between the busbars. The material for the busbars is not particularly limited as long as it makes the formation of the current path possible. In a preferred embodiment, the busbars comprise a transparent and electrically conductive enamel. Due to the transparency of such an enamel, it is not necessary to arrange the busbars in the peripheral region of the pane, the peripheral region being less visible to the observer. Instead, the busbars can also be arranged in the central regions of the pane. This is advantageous, for example, if the heatable coating is not arranged over the entire surface. According to the invention, “over the entire surface” means that at least 95% of a surface is provided with the coating. In a further embodiment of the invention, the busbars are covered by at least one masking strip.

For the purpose of the present invention, “transparent enamel” means that the enamel preferably has a transmittance for visible light of more than 80%, more preferably of more than 90%, even more preferably of more than 95%.

According to the invention, the “peripheral region of the pane” is the region of the pane that is located near the installation position of the pane in the window opening.

The at least one masking strip comprises a colored, preferably black, material, which can preferably be burned into a glass pane. Preferably, the at least one masking strip is opaque in order in particular to serve as visual and UV protection, for example for an adhesive bead.

“Opaque” means a light transmittance of less than 30%, preferably less than 25%, for example less than 5%, and in particular 0%.

The at least one masking strip is a coating made of one or more layers and serves to mask structures that would otherwise be visible through the pane when installed. In particular in the case of a windshield, the masking strip is used to mask an adhesive bead for gluing the windshield into a vehicle body, i.e., it prevents the usually irregularly applied adhesive bead from being seen from the outside, so that a harmonious overall impression of the windshield is created. On the other hand, the masking strip serves as UV protection for the adhesive material used. Permanent irradiation with UV light damages the adhesive material and would release the connection of the pane to the vehicle body over time. The at least one masking strip can also be used, for example, to cover busbars, a temperature sensor, and/or connection elements.

Preferably, a first masking strip is arranged in the peripheral region of the pane between the interior-side surface of the glass pane and the busbars such that it covers the busbars when the pane is viewed from the external environment. Preferably, a second masking strip is also arranged in the peripheral region of the pane such that it covers the busbars when the pane is viewed from the interior. If the pane is designed as a laminated pane, a first masking strip is preferably arranged between the interior-side surface of the outer pane and the busbars and a second masking strip is preferably arranged between the outer surface of the inner pane and the busbars so that these masking strips cover the busbars from both sides of the pane.

In an advantageous embodiment, the heatable coating is a layer or a layer structure of multiple individual layers having a total thickness of less than or equal to 2 μm, particularly preferably less than or equal to 1 μm.

The total layer thickness of the heatable coating is preferably from 40 nm to 300 nm, particularly preferably from 45 nm to 250 nm. In this range for the total thickness of the heatable coating, sufficiently high specific heating power P and, at the same time, sufficiently high transmittance are advantageously achieved at distances h between two busbars that are typical for vehicle panes, in particular windshields, and at an operating voltage U in the range of 12 V to 15 V or 42 V to 48 V. In addition, the heatable coating in this range for the total thickness also has particularly good reflective properties for the infrared range. The total layer thickness of the heatable coating being too low results in a sheet resistance R_{square} that is too high and thus in a specific heating power P that is too low and in reduced reflective properties for the infrared range. The total thickness of the heatable coating being too great reduces the transmittance through the pane too much so that the requirements for the transmittance of vehicle panes are not met.

In one embodiment of the invention, the heatable coating is in the form of thin metal wires, which preferably extend from one peripheral region of the inner or outer pane to the respective opposite peripheral region of the inner or outer pane when the pane is designed as a laminated pane. The wires may also overlap. The diameter of the metal wires is preferably less than 0.5 mm. The metal wires preferably contain at least one metal, for example, silver, gold, copper, nickel, and/or chromium, or a metal alloy. The metal wires particularly preferably contain at least 90 wt. % of the metal, in particular at least 99.9 wt. % of the metal.

The material of the heatable coating is preferably selected such that, depending on the wavelength of the light source used to create the hologram, the smallest possible ghost image is created.

The heatable coating of the pane according to the invention preferably has a sheet resistance of less than or equal to 1 ohm/square, particularly preferably from 0.4 ohm/square to 0.9 ohm/square, most particularly preferably from 0.5 ohm/square to 0.85 ohm/square, for example about 0.7 ohm/square. In this range for the sheet resistance, advantageously high specific heating powers P are achieved. In addition, the heatable coating in this range for the sheet resistance has particularly good reflective properties for the infrared range.

In a preferred embodiment of the invention, the heatable coating is connected in a peripheral region of the pane to two busbars provided for connection to a voltage source, such that a current path for a heating current is formed between the busbars. According to one embodiment, the heatable coating extends over 90% or more on the outer surface or the interior-side surface of the at least one glass pane. This arrangement allows most of the pane to be heated efficiently. In an alternative embodiment, the heatable coating is arranged only in a partial region of the outer surface or the interior-side surface of the at least one glass pane. According to this embodiment, the heatable coating can, for example, be arranged in the regions of the surface in which the at least one hologram element is also arranged, such that a targeted heating of the at least one hologram element can be made possible, which is cost-effective and energy-efficient. Preferably, the at least one hologram element and the heatable coating are not arranged over the entire surface, and the external dimensions of the heatable coating correspond to the external dimensions of the at least one hologram element. This allows energy-efficient temperature stabilization of the at least one hologram element to be achieved, since only the corresponding regions where the at least one hologram element is arranged need to be thermally stabilized, and not the entire pane.

If the pane is designed as a single glass pane, the heatable coating is preferably arranged on the interior-side surface of the glass pane and is located between this surface of the glass pane and the at least one hologram element. According to this embodiment, the at least one hologram element is shielded as well as possible from the external environmental conditions and can additionally be heated by the heatable coating. In addition, the perceptibility of the at least one hologram element is not impaired by the presence of the heatable coating, since, for the viewer in the interior, the heatable coating is arranged behind the at least one hologram element.

On the other hand, if the pane is designed as a laminated pane, the heatable coating and the at least one hologram element are preferably located between the outer pane and the inner pane of the laminated pane since the heatable coating and the at least one hologram element are thus protected from the influences from the external environment. Preferably, for the viewer in the interior, the heatable coating is arranged behind the at least one hologram element, which prevents a reduction in the perceptibility of the at least one hologram element. This can be achieved, for example, in that the heatable coating is arranged on the interior-side surface of the glass pane used as the outer pane and is located between this surface and the at least one hologram element. According to one embodiment, a further layer, e.g., the thermoplastic intermediate layer of the laminated pane, may be located between the heatable coating and the at least one hologram element. In an alternative embodiment, the at least one hologram element is arranged on the outer surface of the glass pane used as the inner pane, and the heatable coating is arranged on the at least one hologram element so that the at least one hologram element is arranged between the heatable coating and this surface. According to one embodiment, a further layer, e.g., the thermoplastic intermediate layer of the laminated pane, may be located between the heatable coating and the at least one hologram element.

Preferably, the heatable coating and the at least one hologram element are arranged in direct contact with each other. This arrangement allows targeted and precise heating of the at least one hologram element directly through the heatable coating.

According to one embodiment of the invention, the heatable coating is structured, for example by laser ablation, in order to direct the electrical flow and the heat generation such that highly homogeneous heating is made possible.

In one embodiment of the invention, at least one of the at least two temperature stabilization elements is a thermally insulating coating. According to the invention, the “thermally insulating coating” is to be understood as a coating that thermally shields the at least one hologram element as well as possible. The thermal shielding of the at least one hologram element is of particular importance when a rapid change in the ambient temperature occurs, which is, for example, caused by rain or snow, or, if the pane is to be used as a vehicle pane, when entering or exiting a tunnel while the vehicle is being driven.

According to an advantageous embodiment, the thermally insulating coating and the at least one hologram element are arranged in direct contact with each other. This arrangement allows targeted thermal shielding of the at least one hologram element to be achieved by the thermally insulating coating.

If the pane is designed as a single glass pane, the thermally insulating coating is preferably arranged between the interior-side surface of the one glass pane and the at least one hologram element. The at least one hologram element can thus be shielded as well as possible from the outside temperature.

If the pane is designed as a laminated pane, the thermally insulating coating is arranged according to one embodiment between the interior-side surface of the at least one glass pane used as the inner pane and the at least one hologram element. This arrangement allows the at least one hologram element to be as far away as possible from the outer side of the pane, which reduces the influence of the outside temperature on the at least one hologram element. In addition, the at least one hologram element in this arrangement is further thermally shielded by the thermally insulating coating.

If the pane is designed as a laminated pane, the thermally insulating coating is arranged according to a further embodiment between the inner pane and the outer pane. In particular, the thermally insulating coating may correspond to the thermoplastic intermediate layer of the laminated pane. In this embodiment, the thickness of the thermoplastic intermediate layer is preferably in the range of 0.4 mm to 4 mm, particularly preferably of 0.6 mm to 2 mm, as a result of which an increased thermal insulation effect can be achieved by the thermoplastic intermediate layer. In this embodiment, the at least one hologram element is preferably arranged on the outer surface of the glass pane used as the inner pane, so that the thermoplastic intermediate layer is located between the at least one hologram element and the outer side of the pane, as a result of which good thermal shielding of the at least one hologram element can be achieved. Alternatively, the at least one hologram element can be laminated between a first thermally insulating coating and a second thermally insulating coating, as a result of which a pane comprises the following structure, starting from the outer side of the pane: outer pane, first thermally insulating coating, the at least one hologram element, second thermally insulating coating, inner pane. In this embodiment, the first thermally insulating coating and the second thermally insulating coating preferably each correspond to the above-defined thermoplastic intermediate layer of the laminated pane.

The material of the thermally insulating coating is not particularly limited as long as it is suitable for thermally shielding the at least one hologram element. Preferably, the material of the thermally insulating coating is a material with a very low thermal conductivity. For example, the thermally insulating coating is selected from at least one plastic of the group consisting of polyvinyl butyral (PVB), an ethylene vinyl acetate copolymer (EVA), and polyurethane (PU) film. In one embodiment, the thermally insulating coating is designed as a transparent aerogel. According to a further embodiment, the at least one masking strip can be used as a thermally insulating coating. The thermally insulating coating can be formed over the entire surface or cover only a portion of a surface. Preferably, the at least one hologram element and the thermally insulating coating are not arranged over the entire surface, and the external dimensions of the thermally insulating coating correspond to the external dimensions of the at least one hologram element. Such an arrangement is sufficient for the thermal insulation effect of the thermally insulating coating on the at least one hologram element. The thickness of the thermally insulating coating is preferably in the range of 0.2 mm to 2 mm, in particular of 0.3 mm to 1 mm. The corresponding thickness can achieve a sufficient thermal insulation effect.

In one embodiment of the invention, at least one of the at least two temperature stabilization elements is an external nozzle with a nozzle opening, wherein the nozzle opening is directed toward the at least one hologram element. In connection with the pane according to the invention, the nozzle is referred to as an “external nozzle” since this nozzle is not part of the pane itself but is arranged externally.

The external nozzle is preferably directed toward the at least one hologram element such that the latter is completely covered by the air flow exiting the external nozzle. The center of the nozzle opening is preferably directed as precisely as possible toward the center of the at least one hologram element. This orientation allows particularly efficient heating or cooling of the at least one hologram element to be achieved by the external nozzle.

According to one embodiment, the external nozzle is encompassed by a heating, ventilation and air conditioning (HVAC) system. This allows the external nozzle to heat or cool the at least one hologram element as needed. In one embodiment, the external nozzle is a nozzle of the HVAC system that is fixedly oriented toward the at least one hologram element and can be operated independently of other nozzles of the HVAC system. According to this embodiment, efficient temperature regulation and stabilization of the at least one hologram element can be achieved by means of the external nozzle, regardless of other settings of the HVAC system.

If the pane is designed as a single glass pane and at least one of the at least two temperature stabilization elements is an external nozzle, the at least one hologram element is preferably arranged on the interior-side surface of the glass pane. On the other hand, if the pane is designed as a laminated pane and at least one of the at least two temperature stabilization elements is an external nozzle, the at least one hologram element is preferably arranged on the interior-side surface of the glass pane used as the inner pane. According to these arrangements, the at least one hologram element can be easily heated or cooled by means of the air jet of the external nozzle.

According to the invention, the pane comprises at least one hologram element, for example one hologram element, and at least two temperature stabilization elements, for example two temperature stabilization elements, wherein the at least two temperature stabilization elements are configured to stabilize the temperature of the at least one hologram element to the target temperature. By using at least two temperature stabilization elements, the most precise possible temperature stabilization can be achieved. In one embodiment of the invention, the pane comprises at least two hologram elements and at least two temperature stabilization elements, wherein one temperature stabilization element each can be configured to stabilize the temperature of a hologram element to the target temperature. The at least two temperature stabilization elements are preferably selected independently of one another from the group consisting of a heatable coating, a thermally insulating coating, and an external nozzle. This means that the specific temperature stabilization elements can be combined as desired. In a preferred embodiment, the at least two temperature stabilization elements correspond to the heatable coating and the external nozzle. This combination of specific temperature stabilization elements can achieve the most precise possible temperature stabilization with the lowest possible consumption of electrical energy.

In one embodiment of the invention, the pane further comprises a temperature sensor configured to measure the temperature of the at least one hologram element. The temperature of the at least one hologram element may be measured directly or indirectly by means of the temperature sensor. For the purpose of the invention, a “direct” measurement means that the temperature of the at least one hologram element itself is measured. On the other hand, an “indirect” measurement means that the temperature of another pane component that is in contact with or in the immediate vicinity of the at least one hologram element is measured.

The temperature sensor is not particularly limited as long as it is suitable for measuring the temperature of the at least one hologram element. The temperature sensor may, for example, be a thermocouple or an IR thermometer.

In one embodiment, the temperature sensor is in contact with the at least one hologram element. This makes it easy to perform a direct temperature measurement of the at least one hologram element. In this embodiment, the temperature sensor is preferably a thermocouple. The thermocouple is preferably arranged in the peripheral region of the pane and covered by at least one masking strip so that the thermocouple is not visible from the outer side and the inner side of the pane. The at least one masking strip corresponds to the at least one masking strip defined above.

If the pane is designed as a single glass pane, a first masking strip is preferably arranged in the peripheral region of the pane between the interior-side surface of the glass pane and the thermocouple such that it covers the thermocouple when the pane is viewed from the external environment. Preferably, a second masking strip is also arranged in the peripheral region of the pane such that it covers the thermocouple when the pane is viewed from the interior. If the pane is designed as a laminated pane, a first masking strip is preferably arranged between the interior-side surface of the outer pane and the thermocouple and a second masking strip is preferably arranged between the outer surface of the inner pane and the thermocouple so that these masking strips cover the thermocouple from the outer side and the inner side of the pane.

In a further embodiment, the temperature sensor is spaced apart from the at least one hologram element. That is to say, there is no direct contact between the at least one hologram element and the temperature sensor. If the temperature sensor is an IR thermometer, it may, for example, be arranged in the dashboard and its measuring range may be oriented toward the at least one hologram element (“direct” measurement). In this case, the at least one hologram element is preferably arranged on the interior-side surface of the glass pane when the pane is designed as a single glass pane and on the interior-side surface of the inner pane when the pane is designed as a laminated pane, so that the measuring range of the IR thermometer is directly oriented toward the at least one hologram element and the temperature thereof can thus be measured directly. On the other hand, if the temperature sensor is a thermocouple, it may, for example, be in contact with the glass pane on which the at least one hologram element is arranged, so that indirect temperature measurement can be performed.

According to one embodiment, the pane may further comprise adhesive layers in order to bond the individual components of the pane together. Preferably, the adhesive layers are made of an optically clear adhesive (OCA), as mentioned above. Suitable optically clear adhesives are known to those skilled in the art.

The invention further relates to a device with thermal stabilization of at least one hologram element, comprising the pane according to the invention, a dashboard, and an HVAC system, wherein the HVAC system comprises at least one nozzle arranged in the dashboard and having a nozzle opening, wherein the nozzle opening is oriented toward the at least one hologram element and the nozzle with the nozzle opening is a temperature stabilization element. This means that the nozzle can represent a temperature stabilization element of the at least two temperature stabilization elements of the pane or an additional temperature stabilization element of the device.

The nozzle with the nozzle opening of the device corresponds to the external nozzle defined above for the pane, wherein the nozzle is arranged in the device itself and not externally. The HVAC system of the device corresponds to the HVAC system defined above for the pane. According to the invention, at least the nozzle with the nozzle opening is used as a temperature stabilization element in the device. In addition to the nozzle with the nozzle opening, the device may further comprise the above-defined heatable coating and/or the above-defined thermally insulating coating as a temperature stabilization element.

In one embodiment, the device further comprises a temperature sensor. The temperature sensor of the device corresponds to the temperature sensor of the pane according to the invention. According to a preferred embodiment, the temperature sensor in the device comprises an IR thermometer arranged in the dashboard and oriented toward the at least one hologram element.

The invention further relates to a method for thermally stabilizing at least one hologram element, wherein the at least one hologram element is arranged in the pane according to the invention or in the device according to the invention, the method comprising at least the steps of:
(a) providing the pane according to the invention or the device according to the invention, and
(b) stabilizing the temperature of the at least one hologram element to the target temperature by means of the at least two temperature stabilization elements.

The embodiments described above in connection with the pane and device according to the invention also apply in the same way to the method according to the invention.

The hologram element may be provided in step (a) as an unexposed hologram element made of light-sensitive material or as the final hologram element with a recorded hologram. It is understood that, when providing the unexposed hologram element in step (a), the method according to the invention comprises the recording of at least one hologram in the hologram element as an additional step.

The provision of the pane according to the invention or the device according to the invention in step (a) is not particularly limited. Method steps for providing the individual elements of the pane or of the device are known to those skilled in the art.

According to the invention, the method is designed for thermally stabilizing at least one hologram element. In particular, the thermal stabilization is realized by step (b) of the method, wherein the temperature of the at least one hologram element is stabilized to the target temperature by means of the at least two temperature stabilization elements. Since temperature regulation of the at least one hologram element is carried out in step (b) only if the measured temperature deviates from the target temperature, the consumption of electrical energy for temperature regulation can be minimized so that the method is energy-efficient and environmentally friendly. In addition, step (b) is preferably performed only if the at least one hologram element is irradiated by a light source, i.e., is active, in order to create a hologram. On the other hand, if the at least one hologram element is not irradiated by a light source in order to create a hologram, i.e., is inactive, step (b) is preferably not performed. Since temperature stabilization preferably only occurs if the at least one hologram element is active, the consumption of electrical energy can be reduced.

Preferably, step (b) comprises at least the following steps in the order:
(i) measuring the temperature of the at least one hologram element by means of the temperature sensor,
(ii) comparing the measured temperature with the target temperature, and
(iii) optionally heating or cooling the at least one hologram element by means of the at least two temperature stabilization elements if the measured temperature deviates from the target temperature.

In one embodiment of the invention, the temperature measured in step (i) is transmitted to a data acquisition device, whereupon this data acquisition device compares the measured temperature with the target temperature in step (ii). Preferably, the target temperature is specified before step (b). If it is determined that the measured temperature deviates from the target temperature, the at least one hologram element is heated or cooled by means of the at least two temperature stabilization elements in step (iii). In one embodiment, a deviation of the measured temperature from the target temperature only exists if the measured temperature is outside a range of (target temperature −10° C.) to (target temperature +10° C.), more preferably of (target temperature −5° C.) to (target temperature +5° C.). That is to say, if the measured temperature is within this range, the at least one hologram element is not heated or cooled. However, if the measured temperature is outside this range, the at least one hologram element is heated or cooled. The data acquisition device itself can send a signal to the at least two temperature stabilization elements, whereupon the at least two temperature stabilization elements heat or cool the at least one hologram element. In a further embodiment, however, the data acquisition device may also be connected to a device for controlling the at least two temperature stabilization elements, to which it sends the result of the comparison from step (ii), whereupon the device for controlling sends a signal to the at least two temperature stabilization elements, whereupon the at least two temperature stabilization elements heat or cool the at least one hologram element.

In one embodiment of the invention, step (b) of the method is performed multiple times so that the temperature of the at least one hologram element can be stabilized over the entire period of use. Preferably, the execution of step (b) is controlled dynamically. For example, rapid control can thus be ensured when there is a significant change in the environmental conditions, such as the occurrence of intense solar radiation, or when starting the vehicle. In one embodiment, step (b) of the method is performed at least every 10 minutes, preferably at least every 8 minutes, more preferably at least every 5 minutes. This is advantageous in stable environmental conditions and at a constant vehicle speed.

If at least one of the at least two temperature stabilization elements according to an embodiment of the invention is a heatable coating, it can heat the at least one hologram element in step (b). In this embodiment, the target temperature is preferably higher than the room temperature of 25° C.

If at least one of the at least two temperature stabilization elements according to an embodiment is an (external) nozzle, it can heat or cool the at least one hologram element in step (b). Since the (external) nozzle is suitable for heating and cooling the at least one hologram element, the target temperature can be chosen arbitrarily, as mentioned above. In this embodiment, the target temperature preferably corresponds to the room temperature of 25° C. The cooling function of the (external) nozzle can also contribute to reducing the influence of thermally induced aging on the at least one hologram element.

The invention also relates to the use of the pane according to the invention as a projection surface for a head-up display. When in use, the pane is suitably mounted in a vehicle or in a building. When used as a projection surface for a head-up display, the pane is preferably designed as a laminated pane.

Head-up displays are known to those skilled in the art and generally comprise an imaging unit and a projection surface. The imaging unit generates the image and may further comprise an optical module, e.g., a mirror optic, which redirects the image onto the projection surface.

The imaging unit comprises an illumination unit, which may, for example, be one or more illumination elements selected from incandescent lamps, gas discharge lamps, light-emitting diodes, and/or laser light sources. Accordingly, visible light or laser light can be used for the illumination.

The visual information is viewed from the space facing the inner pane of the laminated pane. This is generally an interior in which the viewer is located, e.g., a vehicle interior.

The invention is explained in more detail with reference to drawings and exemplary embodiments. The drawings are schematic representations and are not true to scale. The drawings do not limit the invention in any way. In the drawings:

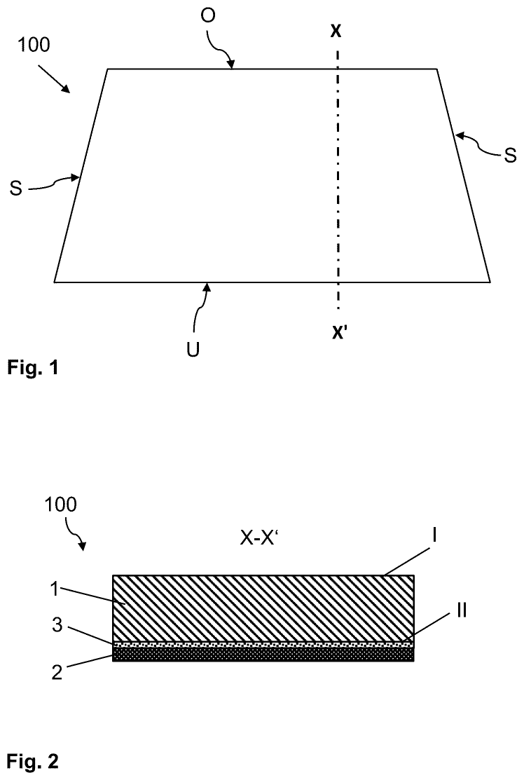

FIG. 1 shows a plan view of an embodiment of a pane 100 according to the invention,

FIG. 2 shows a cross-section through the embodiment of a pane 100 according to the invention shown in FIG. 1, wherein only one of the at least two temperature stabilization elements is shown,

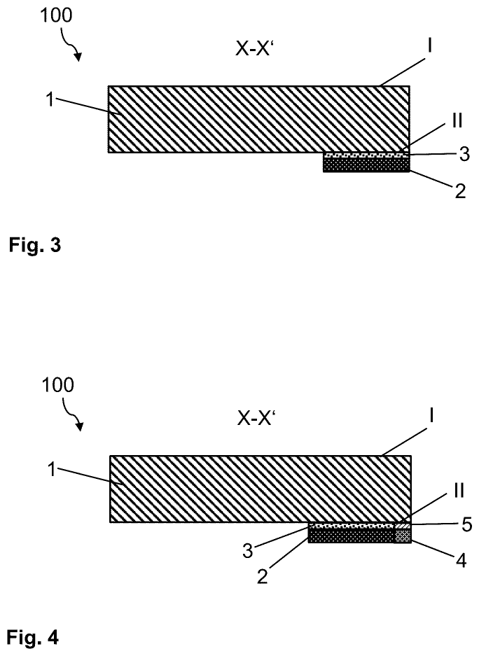

FIG. 3 shows a cross-section through a further embodiment of a pane 100 according to the invention, wherein only one of the at least two temperature stabilization elements is shown,

FIG. 4 shows a cross-section through a further embodiment of a pane 100 according to the invention, wherein only one of the at least two temperature stabilization elements is shown,

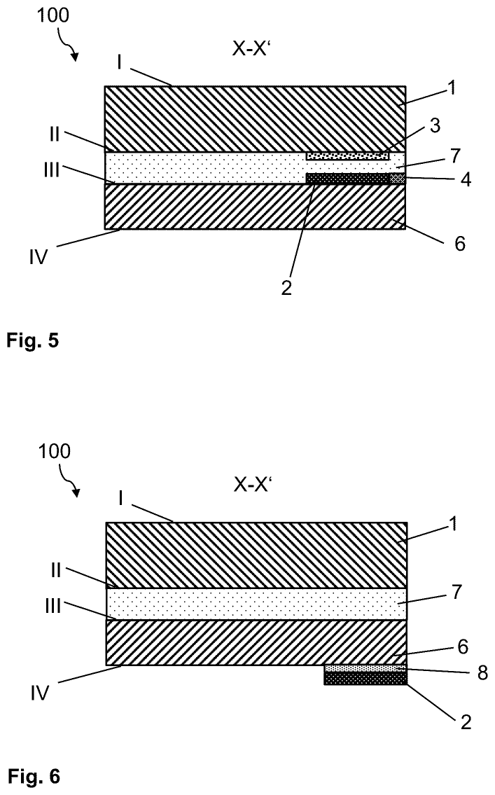

FIG. 5 shows a cross-section through a further embodiment of a pane 100 according to the invention, wherein only one of the at least two temperature stabilization elements is shown,

FIG. 6 shows a cross-section through a further embodiment of a pane 100 according to the invention, wherein only one of the at least two temperature stabilization elements is shown,

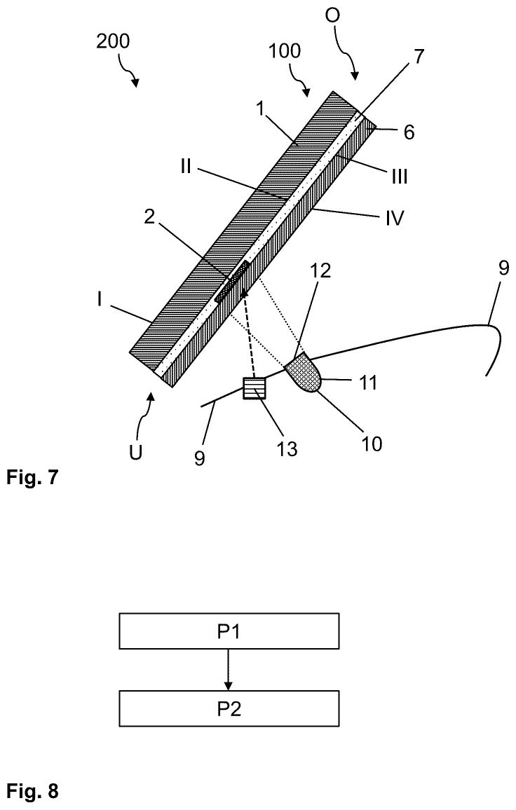

FIG. 7 shows a cross-section through an embodiment of a device 200 according to the invention, wherein only one of the at least two temperature stabilization elements is shown,

FIG. 8 shows an exemplary embodiment of a method according to the invention using a flowchart.

FIG. 1 shows a plan view of an embodiment of a pane 100 according to the invention. In the embodiment shown in FIG. 1, the pane 100 has an upper edge O, a lower edge U, and two side edges S.

FIG. 2 shows a cross-section along the section line X-X′ through the embodiment of a pane 100 according to the invention shown in FIG. 1. The pane 100 comprises a glass pane 1 having an outer surface I and an interior-side surface II, a hologram element 2 arranged on the interior-side surface II of the glass pane 1, and a temperature stabilization element 3 arranged between the interior-side surface Il of the glass pane 1 and the hologram element 2. According to the invention, the pane 100 comprises at least one further temperature stabilization element, which is, however, not shown in FIG. 2. This at least one further temperature stabilization element can be selected from the group consisting of a heatable coating, a thermally insulating coating, and an external nozzle. In the embodiment shown in FIG. 2, the hologram element 2 and the temperature stabilization element 3 are present over the entire surface. In particular, one of the at least two temperature stabilization elements in this embodiment is a heatable coating 3. It is understood that further layers may also be present in the pane 100. Preferably, the hologram element 2 is laminated between two polyvinyl butyral (PVB) films, two ethylene vinyl acetate (EVA) films, or two films made of thermoplastic polyurethane (TPU) (not shown). In addition, the pane 100 may further comprise adhesive layers (not shown) in order to bond the individual components of the pane 100 together. Preferably, the adhesive layers are formed from an optically clear adhesive.

The glass pane 1 consists, for example, of soda lime glass and is 2.1 mm thick.

In the embodiment shown in FIG. 2, the hologram element 2 comprises a photopolymer, wherein the hologram element 2 is formed as a coating on the heatable coating 3 and has a thickness of, for example, 100 μm. Optionally, the hologram element 2 may comprise a substrate layer in addition to the photopolymer, wherein the substrate layer is arranged directly adjacent to the heatable coating 3.

FIG. 3 shows a cross-section of a further embodiment of a pane 100 according to the invention. The pane 100 shown in cross-section in FIG. 3 differs from that shown in FIG. 2 in that the hologram element 2 and the heatable coating 3 are not formed over the entire surface and the external dimensions of the heatable coating 3 correspond to the external dimensions of the hologram element 2.

FIG. 4 shows a cross-section of a further embodiment of a pane 100 according to the invention. The pane 100 shown in cross-section in FIG. 4 differs from that shown in FIG. 3 in that the pane 100 further comprises a temperature sensor 4. The temperature sensor 4 is in direct contact with the hologram element 2 and can measure the temperature thereof. If the measured temperature is lower than the target temperature, the hologram element 2 can be heated by the heatable coating 3. Preferably, the temperature sensor 4 has no contact with the heatable coating 3. This can be ensured, for example, by the pane 100 having a thermally insulating coating 5 which is located between the interior-side surface II of the glass pane 1 and the temperature sensor 4 and which spaces the heatable coating 3 and the temperature sensor 4 apart from each other. In the embodiment shown in FIG. 4, the external dimensions of the thermally insulating coating 5 correspond to the external dimensions of the temperature sensor 4. In the embodiment shown, the temperature sensor 4 is arranged in the peripheral region of the pane 100. Preferably, in the peripheral region of the pane 100, a first masking strip (not shown) is arranged between the interior-side surface II of the glass pane 1 and the temperature sensor 4 such that it covers the temperature sensor 4 from the outer side of the pane 100. Preferably, a second masking strip (not shown) is further arranged in the peripheral region of the pane 100 such that it covers the temperature sensor 4 from the inner side of the pane 100. Preferably, the temperature sensor 4 is fastened in the pane 100 by means of an adhesive layer (not shown), for example a layer made of an optically clear adhesive.

FIG. 5 shows a cross-section of a further embodiment of a pane 100 according to the invention. The pane 100 shown in cross-section in FIG. 5 differs from that shown in FIG. 4 in that the pane 100 is designed as a laminated pane, wherein the glass panes 1 and 6 are connected via a thermoplastic intermediate layer 7. The glass pane 1 is an outer pane, and the glass pane 6 is an inner pane. In the laminated pane, the glass pane may be present as the outer pane 1 and the further glass pane may be present as the inner pane 6 or the glass pane may be present as the inner pane 6 and the further glass pane may be present as the outer pane 1. In the embodiment shown, the heatable coating 3 is arranged on the interior-side surface II of the outer pane 1, and the hologram element 2 and the temperature sensor 4 are arranged on the outer surface III of the inner pane 6, while the thermoplastic intermediate layer 7 is located between the heatable coating 3 and the hologram element 2. As an alternative to the embodiment shown, the heatable coating 3 may also be arranged in direct contact with the hologram element 2. In the embodiment shown, the temperature sensor 4 is arranged in the peripheral region of the pane 100. Preferably, in the peripheral region of the pane 100, a first masking strip (not shown) is arranged between the interior-side surface II of the glass pane 1 and the temperature sensor 4 such that it covers the temperature sensor 4 from the outer side of the pane 100. Preferably, a second masking strip (not shown) is further arranged between the outer surface III of the inner pane 6 and the temperature sensor 4 such that it covers the temperature sensor 4 from the inner side of the pane 100.

It is understood that further layers may also be present in the pane 100. Preferably, the hologram element 2 is laminated between two polyvinyl butyral (PVB) films, two ethylene vinyl acetate (EVA) films, or two films made of thermoplastic polyurethane (TPU) (not shown). In addition, the pane 100 may further comprise adhesive layers (not shown) in order to bond the individual components of the pane 100 together. Preferably, the adhesive layers are formed from an optically clear adhesive.

The glass pane 1 consists, for example, of soda lime glass and is 2.1 mm thick. The glass pane 6 consists, for example, of soda lime glass and is 1.6 mm thick.

The thermoplastic intermediate layer 7 consists, for example, of polyvinyl butyral (PVB) and is 0.76 mm thick.

FIG. 6 shows a cross-section of a further embodiment of a pane 100 according to the invention. In the embodiment shown, the pane 100 is designed as a laminated pane, as described above for FIG. 5. The hologram element 2 is arranged on the interior-side surface IV of the inner pane 6. A thermally insulating coating 8 is located between the hologram element 2 and the interior-side surface IV of the inner pane 6. By being arranged on the interior-side surface IV of the inner pane 6, the hologram element 2 can be protected as well as possible from external weather conditions. The thermally insulating coating 8 additionally makes thermal shielding of the hologram element 2 and thus thermal stabilization thereof possible. In the pane 100 shown in FIG. 6, the hologram element 2 and the thermally insulating coating 8 are not formed over the entire surface, and the external dimensions of the thermally insulating coating 8 correspond to the external dimensions of the hologram element 2. According to the invention, the pane 100 comprises at least one further temperature stabilization element, which is, however, not shown in FIG. 6. This at least one further temperature stabilization element can be selected from the group consisting of a heatable coating, a thermally insulating coating, and an external nozzle.

It is understood that further layers may also be present in the pane 100. Preferably, the hologram element 2 is laminated between two polyvinyl butyral (PVB) films, two ethylene vinyl acetate (EVA) films, or two films made of thermoplastic polyurethane (TPU) (not shown). In addition, the pane 100 may further comprise adhesive layers (not shown) in order to bond the individual components of the pane 100 together. Preferably, the adhesive layers are formed from an optically clear adhesive.

FIG. 7 shows a cross-section of an embodiment of a device 200 according to the invention. In the embodiment, the device 200 comprises a pane 100 according to the invention. The pane 100 is designed as a laminated pane, as described above for FIG. 5. The hologram element 2 is arranged on the outer surface III of the inner pane 6. Alternatively, the hologram element 2 may also be arranged on the interior-side surface II of the outer pane 1 or the interior-side surface IV of the inner pane 6. The device 200 according to the embodiment further comprises a dashboard 9, an HVAC system 10, wherein the HVAC system 10 comprises a nozzle 11 arranged in the dashboard 9 and having a nozzle opening 12, wherein the nozzle opening 12 is oriented toward the at least one hologram element 2 and the nozzle 11 with the nozzle opening 12 is a temperature stabilization element, and a temperature sensor which is an IR thermometer 13. By means of the IR thermometer 13, the temperature of the hologram element 2 itself or, depending on the arrangement position of the hologram element 2, the ambient temperature of the hologram element 2 can be measured. This is shown in FIG. 7 by the dashed arrow. Depending on the measurement result, the temperature of the hologram element 2 can be regulated by means of the nozzle 11. If the measured temperature is lower than the target temperature, the hologram element 2 can be heated by the air flow exiting the nozzle opening 12 (indicated by the dashed lines in FIG. 7). Alternatively, if the measured temperature is higher than the target temperature, the hologram element 2 can be cooled by the air flow exiting the nozzle opening 12. According to the invention, the pane 100 comprises at least one further temperature stabilization element, which is, however, not shown in FIG. 7. This at least one further temperature stabilization element can be selected from the group consisting of a heatable coating, a thermally insulating coating, and an external nozzle.

FIG. 8 shows an exemplary embodiment of the method according to the invention for thermally stabilizing at least one hologram element 2 using a flowchart, wherein the at least one hologram element 2 is arranged in the pane 100 according to the invention or in the device 200 according to the invention, the method comprising at least the steps of:
P1 providing the pane 100 or the device 200, and
P2 stabilizing the temperature of the at least one hologram element 2 to the target temperature by means of the at least two temperature stabilization elements 3, 8, 11.

### List of Reference Signs

1 Glass pane/outer pane
2 Hologram element
3 Heatable coating
4 Temperature sensor
5 Thermally insulating coating
6 Glass pane/inner pane
7 Thermoplastic intermediate layer
8 Thermally insulating coating
9 Dashboard
10 HVAC system
11 Nozzle
12 Nozzle opening
13 IR thermometer
100 Pane
200 Device
I Outer surface of the glass pane/outer pane 1
II Interior-side surface of the glass pane/outer pane 1
III Outer surface of the glass pane/inner pane 6
IV Interior-side surface of the glass pane/inner pane 6
O Upper edge
U Lower edge
S Side edge
X-X′ Section line

1. A pane with thermal stabilization of at least one hologram element, comprising:
at least one glass pane having an outer surface and an interior-side surface,
at least one hologram element arranged on the outer surface or the interior-side surface of the at least one glass pane, wherein the at least one hologram element comprises a photopolymer, and
at least two temperature stabilization elements, wherein the at least two temperature stabilization elements are configured to stabilize the temperature of the at least one hologram element to a target temperature.

2. The pane according to claim 1, wherein at least one of the at least two temperature stabilization elements is a heatable coating.

3. The pane according to claim 1, wherein at least one of the at least two temperature stabilization elements is a thermally insulating coating arranged between the interior-side surface of the at least one glass pane and the at least one hologram element.

4. The pane according to claim 2, wherein the at least one hologram element and the heatable coating are not arranged over the entire surface and external dimensions of the heatable coating correspond to external dimensions of the at least one hologram element.

5. The pane according to claim 3, wherein the at least one hologram element and the thermally insulating coating are not arranged over the entire surface and external dimensions of the thermally insulating coating correspond to external dimensions of the at least one hologram element.

6. The pane according to claim 1, wherein at least one of the at least two temperature stabilization elements is an external nozzle with a nozzle opening, wherein the nozzle opening is oriented toward the at least one hologram element.

7. The pane according to claim 1, further comprising a temperature sensor configured to measure the temperature of the at least one hologram element.

8. The pane according to claim 7, wherein the temperature sensor is in contact with the at least one hologram element.

9. The pane according to claim 2, wherein the heatable coating is provided with busbars connected to the poles of a voltage source, and the busbars comprise a transparent and electrically conductive enamel.

10. The pane according to claim 1, which is designed as a laminated pane, wherein the glass panes are connected via a thermoplastic intermediate layer.

11. A device with thermal stabilization of at least one hologram element, comprising:
the pane according to claim 1,
a dashboard, and
an HVAC system,
wherein the HVAC system comprises at least one nozzle arranged in the dashboard and having a nozzle opening, wherein the nozzle opening is oriented toward the at least one hologram element and the nozzle with the nozzle opening is a temperature stabilization element.

12. The device according to claim 11, wherein the pane comprises an IR thermometer as a temperature sensor, which is arranged in the dashboard and is oriented toward the at least one hologram element.

13. A method for thermally stabilizing at least one hologram element, wherein the at least one hologram element is arranged in the pane according to claim 1, the method comprising at least the steps of:
(a) providing the pane or the device, and
(b) stabilizing the temperature of the at least one hologram element to the target temperature by means of the at least two temperature stabilization elements.

14. The method according to claim 13, wherein step (b) comprises at least the following steps in the order:
(i) measuring the temperature of the at least one hologram element by means of the temperature sensor,
(ii) comparing the measured temperature with the target temperature, and
(iii) optionally heating or cooling the at least one hologram element by means of the at least two temperature stabilization elements if the measured temperature deviates from the target temperature.

15. Use of the pane according to claim 1 as a projection surface for a head-up display.
